(19) United States
(12) Patent Application Publication
(10) Pub. No.: US 2008/0131987 A1
(43) Pub. Date: Jun. 5, 2008

(54) METHOD FOR FABRICATING LIGHT-EMITTING DEVICE

(75) Inventors: Kazuhiko Horino, Yamanashi (JP); Akito Kuramata, Yamanashi (JP); Hiroshi Yamamoto, Yamanashi (JP); Toshimitsu Kaneko, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Yamanashi (JP)

(21) Appl. No.: 11/948,394

(22) Filed: Nov. 30, 2007

(30) Foreign Application Priority Data
Nov. 30, 2006 (JP) 2006-324579

(51) Int. Cl. H01L 33/00

(52) U.S. Cl. 438/43; 257/E33.006

(57) ABSTRACT

A method for fabricating a light-emitting device includes: forming a first semiconductor layer on a substrate; foaming an active layer on the first semiconductor layer; forming a second semiconductor layer on the active layer, the second semiconductor layer having a conduction type opposite to that of the first semiconductor layer; and forming a recess so as to be penetrated through up to the first semiconductor layer from the second semiconductor layer by a first etching; and forming an inversely tapered shape to an inner wall of the recess by a second etching using an etching solution.

### BACKGROUND OF THE INVENTION

1. Field of the Invention

The present invention generally relates to methods for fabricating light-emitting devices, and more particularly, to a method for fabricating a light emitting device having a recess.

2. Description of the Related Art

The light-emitting device is capable of emitting light, such as LED (Light Emitting Diode) or LD (Laser Diode), and is used for optical communications and storage devices using optical storage media. For example, a light-emitting device having a GaN-based semiconductor using a sapphire (Al₂O₃) substrate attracts attention as a device capable of emitting blue light. The GaN-based semiconductor may be, for example, GaN (gallium nitride), AlGaN that is a mixed crystal of GaN and AlN (aluminum nitride), or InGaN that is a mixed crystal of GaN and InN (indium nitride).

A key factor for realizing high-luminance light-emitting devices is the efficiency of extracting light generated in an active layer to the outside. FIG. 1 is a cross-sectional view of a general GaN-based semiconductor light-emitting device (first related art). Referring to FIG. 1, there are illustrated an n-type GaN layer 12, an active layer 14 and a p-type GaN layer 16 are provided on a sapphire substrate 10 in that order. Hereinafter, a laminate of the n-type GaN layer 12, the active layer 14 and the p-type GaN layer 16 is referred to a GaN semiconductor layer 13. The relative index of sapphire is approximately equal to 1.7, and the relative index of GaN is approximately equal to 2.4. Thus, the GaN semiconductor layer is sandwiched between air having a small relative index and sapphire. Thus, as shown in FIG. 2, light that is emitted in the active layer 14 and is incident to a light extraction surface 20 of the p-type GaN layer 16 within the critical angle (±24°) is emitted outside of the device through the light extraction surface 20. In contrast, light incident to the light extraction surface 20 at angles equal to or greater than the critical angle are laterally propagated through the GaN semiconductor layer 13 with reflections. The most of light laterally propagated is emitted outside of the device through a side surface of the light-emitting device. Even the light emitted from the side surface of the light-emitting device can be detected as an optical output. However, light is absorbed during propagation through the active layer 14. This is loss and degrades the efficiency of light extraction.

There have been several proposals for efficiently extracting light generated in the active layer 14 from the light extraction surface 20 to the outside of the device. For example, Japanese Patent No. 3691951 (document D1) discloses an improvement in light extraction by forming a hole in the GaN semiconductor layer 13. FIG. 3 is a cross-sectional view of a GaN-based semiconductor device disclosed in document D1 (second related art). A hole 22 is formed in the GaN semiconductor layer 13 so that the hole 22 is penetrated through the p-type GaN layer 16 and the active layer 14, and is partially formed in the layer 12 in the thickness direction without being penetrated therethrough. The other structures are the same as those of the first related art shown in FIG. 1. Part of light laterally propagated through the GaN semiconductor layer 13 is refracted towards the light extraction surface 20 when passing through the hole 22, and is emitted outwards. Thus, the efficiency of light extraction can be improved.

Japanese Patent No. 3767420 (document D2) discloses a wedge-shaped reflection groove in the GaN semiconductor layer 13 for the purpose of improving light extraction. FIG. 4 is a cross-sectional view of a GaN-based semiconductor device disclosed in document D2 (third related art). The GaN semiconductor layer 13 is formed on one of the opposite main surfaces of the sapphire substrate 10. Wedge-shaped reflection grooves 24 are formed in the GaN semiconductor layer 13. The light extraction surface 20 is the surface of the substrate 10 opposite to the other main surface on which the GaN semiconductor layer 13 is formed. According to the third related art, light that is generated in the active layer 14 and is almost half of light laterally propagated through the GaN semiconductor layer 13 is reflected by the reflection grooves 24 towards the light extraction surface 20, and is emitted outside of the device through the light extraction surface 20. Thus, the efficiency of light extraction can be improved.

Japanese Patent Application Publication No. 2003-69075 (document D3) discloses a technique of shaping the surface of the light extraction surface 20 into a relief structure for the purpose of improving light extraction (fourth related art). FIG. 5 is a cross-sectional view of a GaN-based semiconductor device disclosed in document D3. The GaN semiconductor layer 13 is formed on one of the opposite main surfaces of the sapphire substrate 10. The light extraction surface 20 is the surface of the substrate 10 opposite to the other main surface on which the GaN semiconductor layer 13 is formed. The light extraction surface 20 has a relief structure, which form multiple different directions of critical angle. Even light that is incident to the flat light extraction surface at angles greater than or equal to the critical angle and is reflected by the flat surface 20 can be emitted outside of the device through the present light extraction surface 20 with a relief structure due to the multiple different directions of critical angle. Thus, light can be emitted more efficiently.

Japanese Patent No. 3723843 (document D4) discloses a lattice arrangement of convex portions formed on the light extraction surface 20 at intervals shorter than the wavelength of light emitted outside.

However, the first through fourth related arts have the following problems to be solved.

The GaN-based semiconductor device disclosed in document D1 the most of light that enters into the hole 22 is incident to the GaN semiconductor layer 13 again. As shown in FIG. 6, the hole 22 may be made wider in the direction of light propagation so that the amount of light emitted outside of the device through the light extraction surface 20 can be increased. However, there is still light that is incident to the GaN semiconductor layer 13 again. Further, the wider hole 22 decreases the area of the active layer 14 and may result in a reduced amount of light emission. Furthermore, the hole 22 is vertically formed in the sapphire substrate 10. Thus, light propagated in the vertical direction of the substrate 10 cannot be extracted outside of the device through the light extraction surface 20.

In the GaN-based semiconductor device disclosed in document D2, the most of light that is laterally propagated through the GaN semiconductor layer 13 and enters into the reflection grooves 24 is externally emitted from the reflection grooves 24. Thus, the above light cannot be extracted through the light extraction surface 20.

In the GaN-based semiconductor device disclosed in document D3, there is a difficulty in extraction of light that is horizontally propagated through the substrate 10.

In the GaN-based semiconductor device disclosed in document D4, it is difficult to form the recess in the sapphire substrate 10 because sapphire is very rigid.

### SUMMARY OF THE INVENTION

The present invention has been made in view of the above circumstances, and provides a method for fabricating a light-emitting device that is capable of improving the efficiency in light extraction.

According to an aspect of the present invention, there is provided a method for fabricating a light-emitting device including: forming a first semiconductor layer on a substrate; forming an active layer on the first semiconductor layer; forming a second semiconductor layer on the active layer, the second semiconductor layer having a conduction type opposite to that of the first semiconductor layer; and forming a recess so as to be penetrated through up to the first semiconductor layer from the second semiconductor layer by a first etching; and forming an inversely tapered shape to an inner wall of the recess by a second etching using an etching solution.

### BRIEF DESCRIPTION OF THE DRAWINGS

FIG. 1 is a cross-sectional view of a GaN-based semiconductor light-emitting device in accordance with a first related art;

FIG. 2 is a cross-sectional view of performance of the first related art;

FIG. 3 is a cross-sectional view of a GaN-based semiconductor light-emitting device in accordance with a second related art and its performance;

FIG. 4 is a cross-sectional view of a GaN-based semiconductor light-emitting device in accordance with a third related art and its performance;

FIG. 5 is a cross-sectional view of a GaN-based semiconductor light-emitting device in accordance with a fourth related art and its performance;

FIG. 6 is a cross-sectional view showing a problem of the GaN-based semiconductor light-emitting device of the second related art;

FIG. 7A is a plan view of a light-emitting device in accordance with a first comparative example, and FIG. 7B is a cross-sectional view taken along a line A-A shown in FIG. 7A;

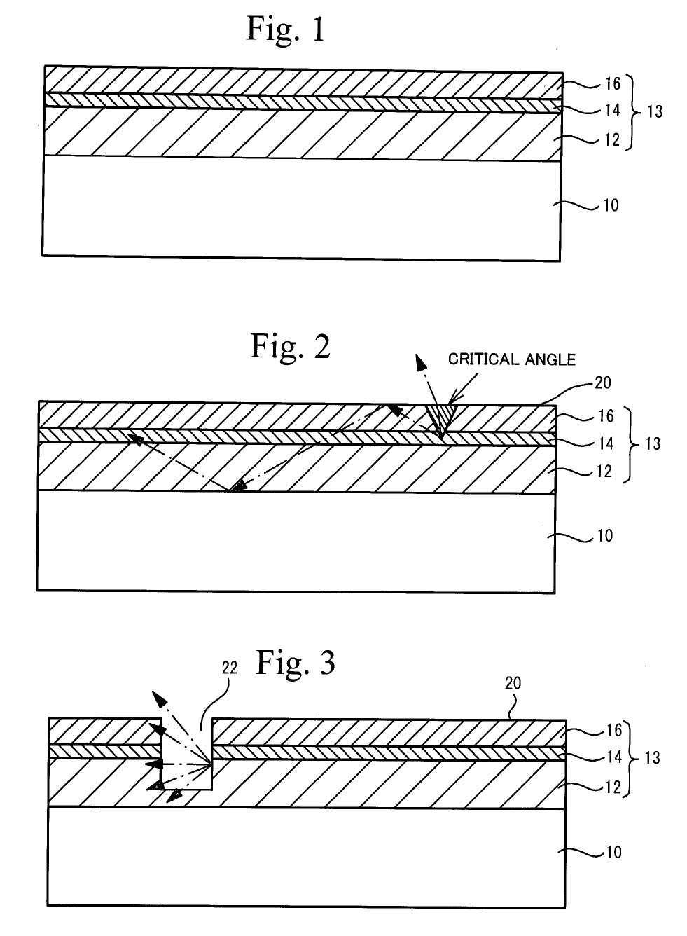

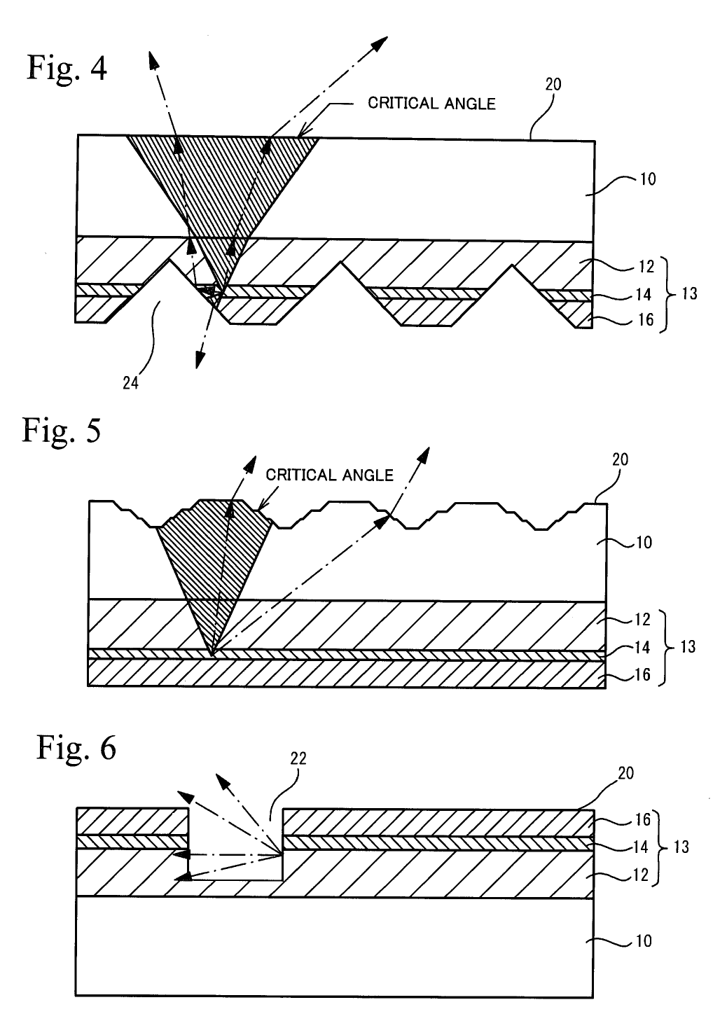

FIG. 5A is a plan view of a light-emitting device in accordance with a first embodiment, and FIG. 5B is a cross-sectional view taken along a line A-A shown in FIG. 8A;

FIG. 9 is a cross-sectional view of SEM taken along a line B-B shown in FIG. 8A;

FIGS. 10A through 10C are respectively cross-sectional views showing a first part of a first method for fabricating the light-emitting device in accordance with the first embodiment;

FIGS. 11A through 11C are respectively cross-sectional views showing a second part of the first method;

FIGS. 12A through 12C are respectively cross-sectional views showing a third part of the first method;

FIGS. 13A through 13C are respectively cross-sectional views showing a first part of a second method for fabricating the light-emitting device in accordance with the first embodiment;

FIGS. 14A through 14C are respectively cross-sectional views showing a second part of the second method;

FIG. 15 is a cross-sectional view showing a third part of the second method;

FIG. 16 shows light output vs. current characteristics of the light-emitting devices of the first embodiment and the first comparative example;

FIG. 17 shows effects of the light-emitting device in accordance with the first embodiment;

FIG. 18A shows a relationship between the efficiency of light extraction and an angle of a side surface of the light-emitting device of a second comparative example, and FIG. 18B is a cross-sectional view of the second comparative example;

FIG. 19A is a plan view of a light-emitting device in accordance with a second embodiment; and FIG. 19B is a cross-sectional view taken along a line A-A shown in FIG. 19A;

FIG. 20 shows a cross-section of a light-emitting device in accordance with a third embodiment and its performance; and

FIG. 21 is a cross-sectional view of a light-emitting device in accordance with a fourth embodiment.

### DESCRIPTION OF THE PREFERRED EMBODIMENTS

A description will now be given of embodiments of the present invention with reference to the accompanying drawings.

### First Embodiment

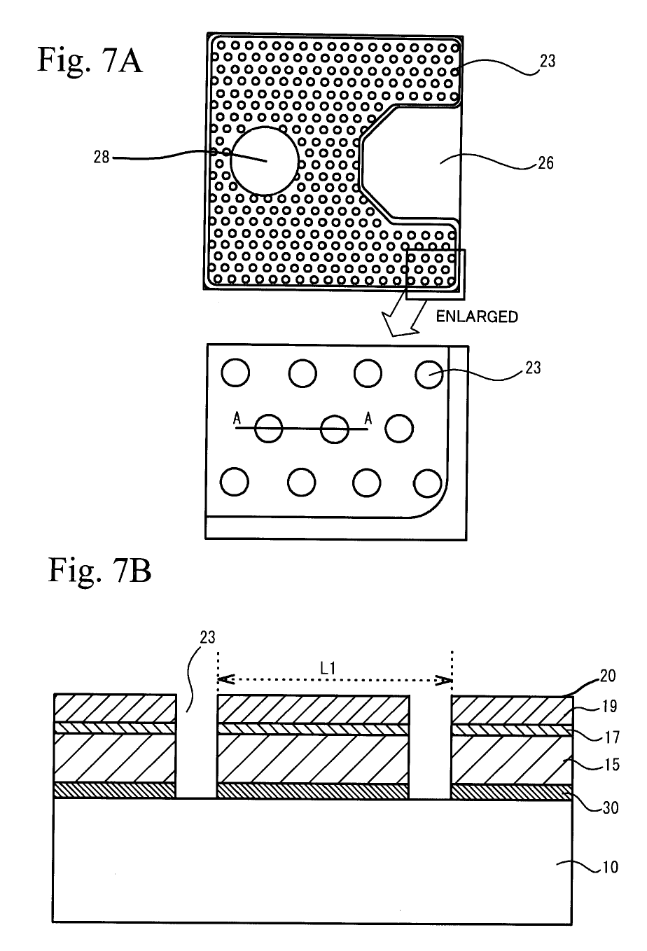

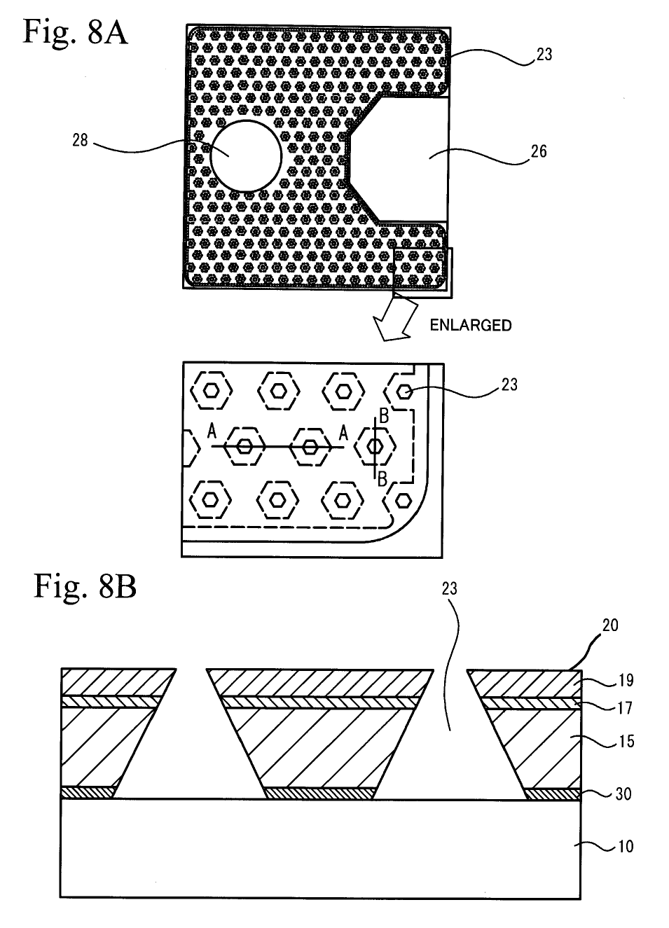

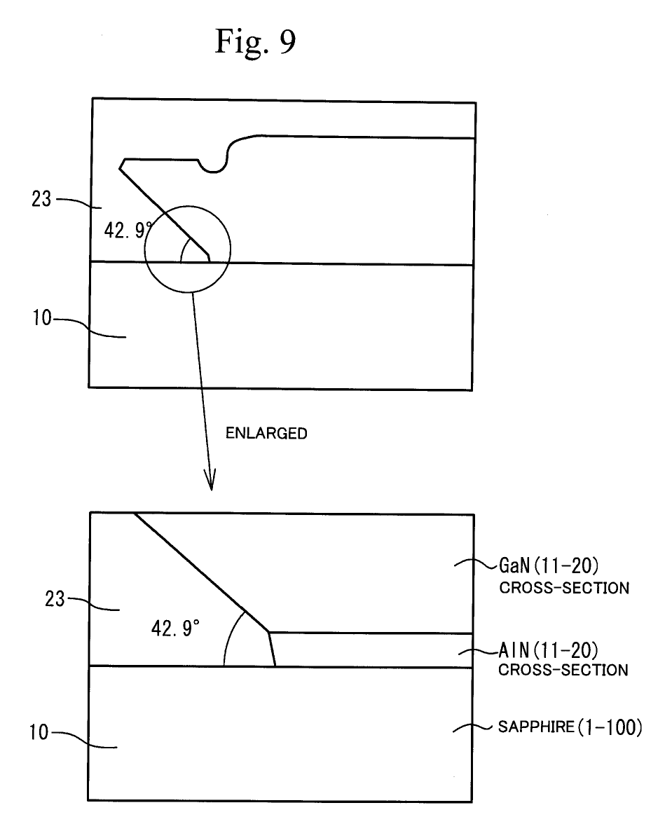

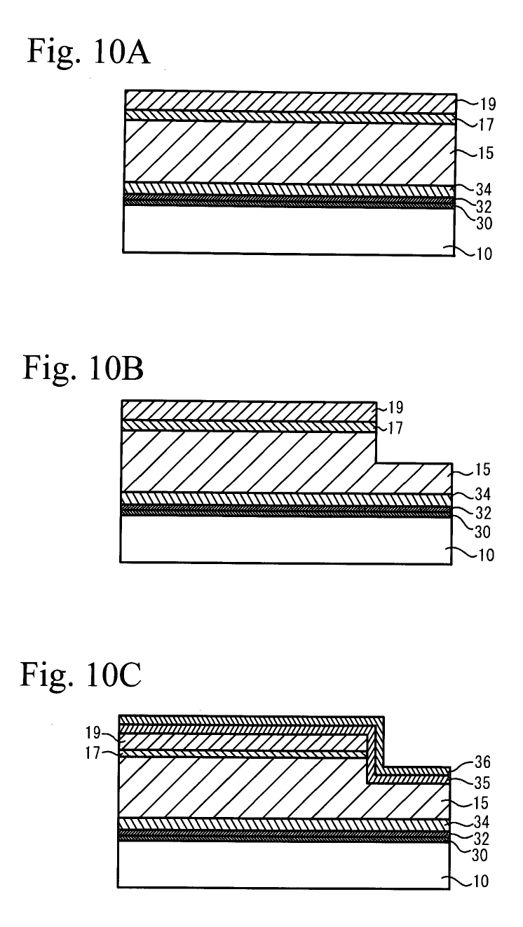

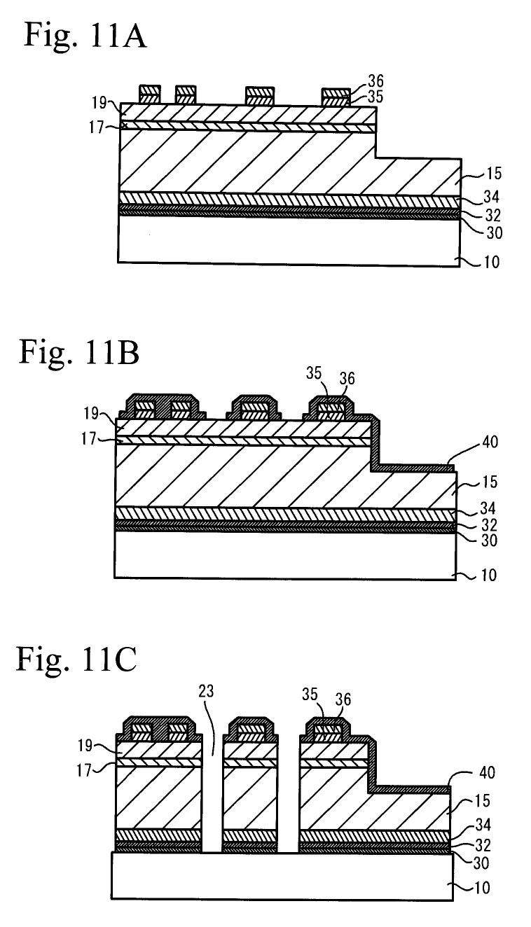

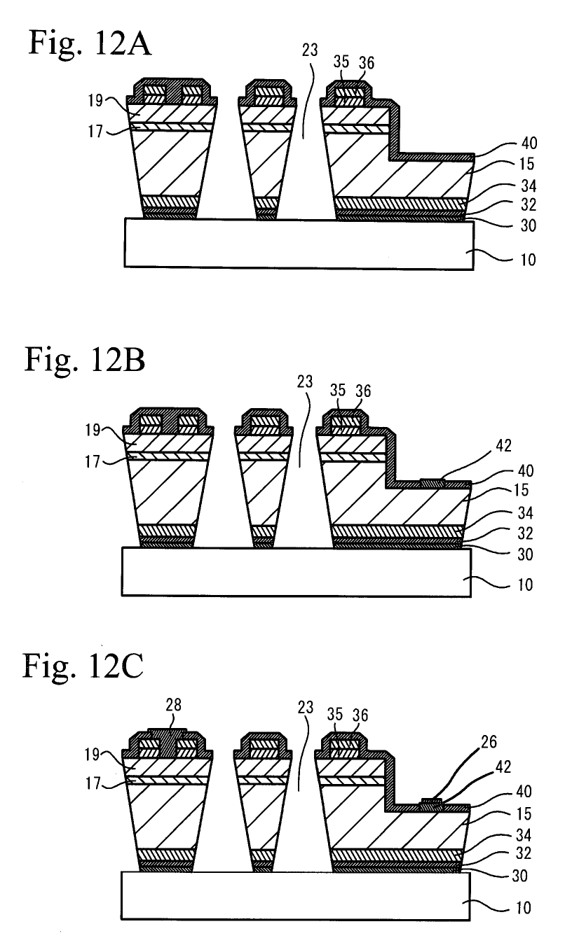

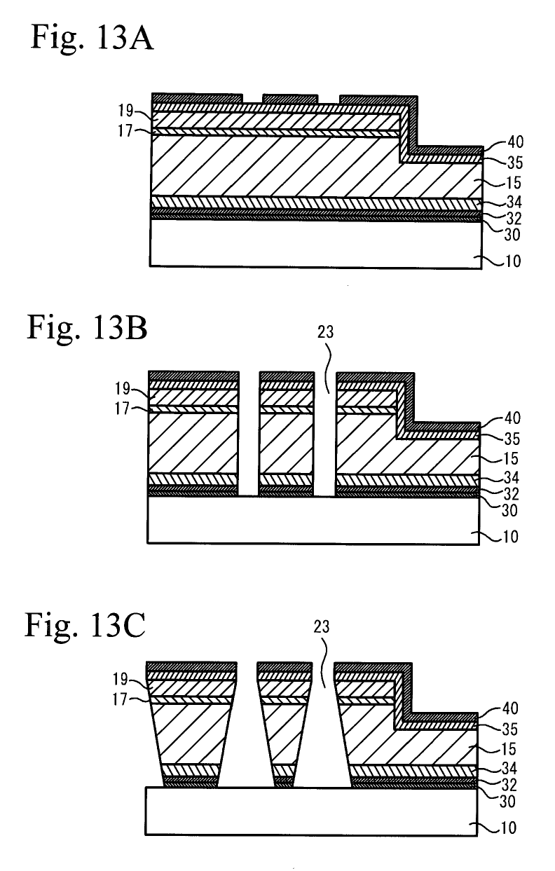

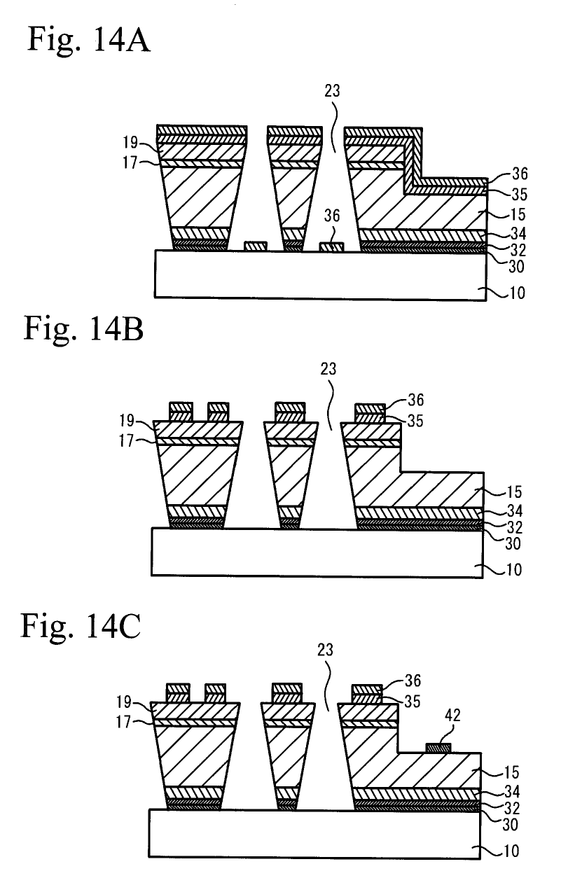

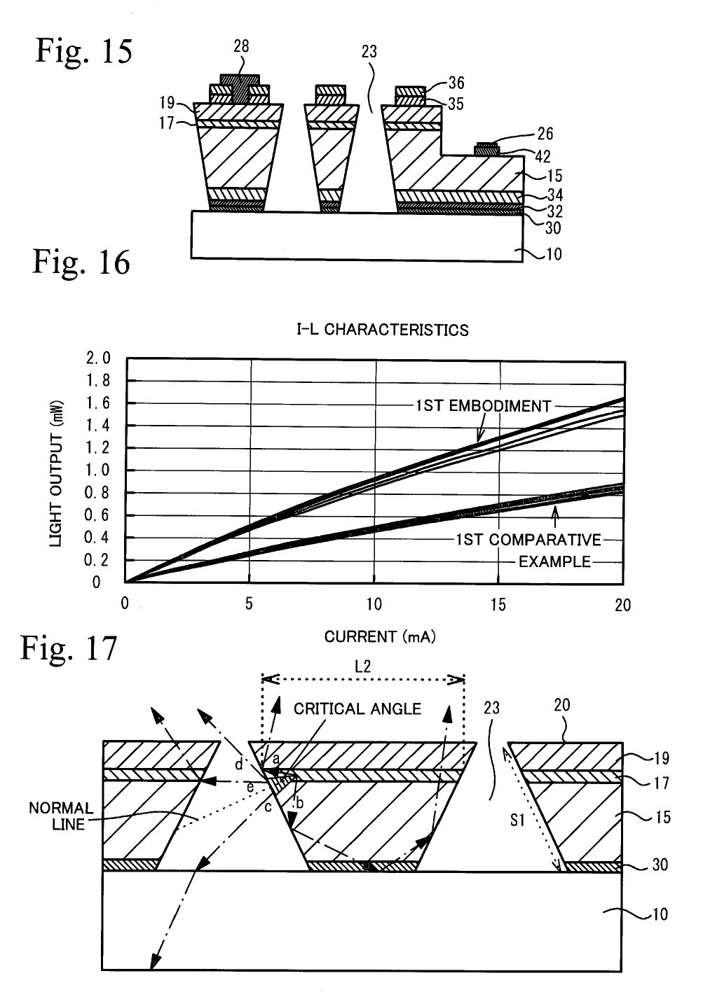

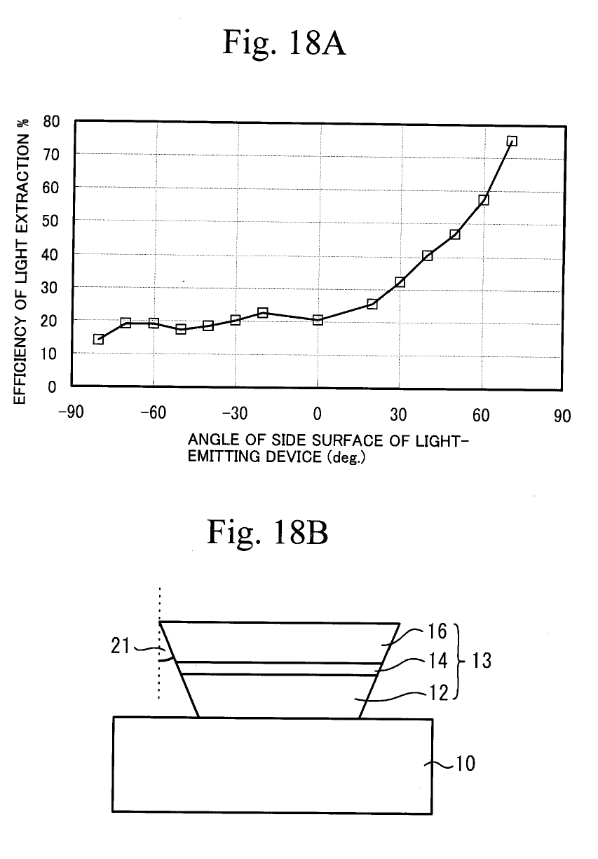

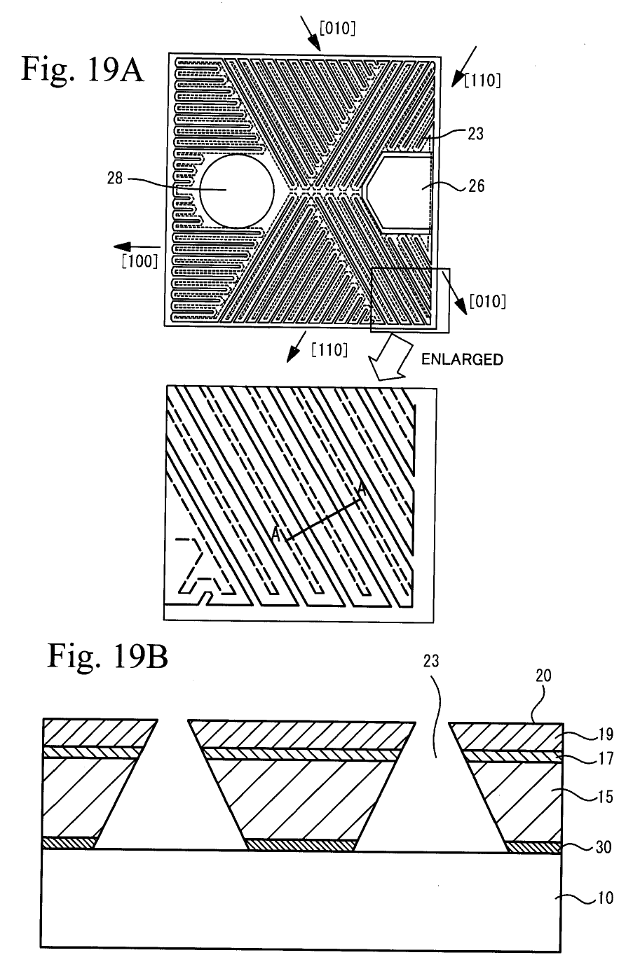

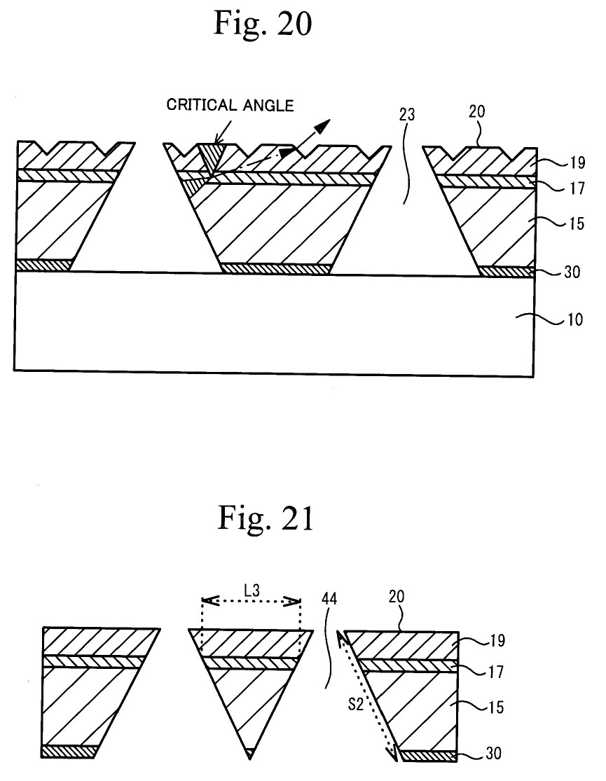

A first embodiment will now be described together with a first comparative example. FIG. 7A is a plan view of a light-emitting device in accordance with the first comparative example, and FIG. 7B is a cross-sectional view taken along a line A-A shown in FIG. 7A. FIG. 8A is a plan view of a light-emitting device in accordance with the first embodiment, and FIG. 85 is a cross-sectional view taken along a line A-A shown in FIG. 8A.

Referring to FIG. 7A, recesses 23 formed by circular holes are provided between an n-type electrode pad 26 and a p-type electrode pad 28. A third semiconductor layer 30, which may be AlN layer, is provided on the sapphire substrate 10. On the third semiconductor layer 30, provided are a first semiconductor layer 15 formed by the n-type GaN layer, an active layer 17 formed by a multiple layer of InGaN/GaN, and a second semiconductor layer 19 formed by a p-type GaN layer in that order The second semiconductor layer 19 has a conduction type opposite to that of the first semiconductor layer 15. The recesses 23 are formed so as to be penetrated through the third semiconductor layer 30, the first semiconductor layer 15, the active layer 17 and the second semiconductor layer 19. The recesses 23 are arranged at intervals L1 approximately equal to 20 μm, and have a diameter of approximately 2 μm. The recesses 23 are approximately 4.2 μm deep. The light extraction surface 20 is a surface of the second semiconductor layer 19. FIGS. 7A and 7B do not illustrate a Si-doped GaN layer 32, an undoped GaN layer 34, an ITO layer 35, an ITO layer 36 and an SiO2 (silicon oxide) 40 for the sake of simplicity. Similarly, these layers are omitted in FIGS. 8B, 17, 19B, 20 and 21.

Referring to FIGS. 8A and 8B, the recesses 23 have a shape of a six-sided pyramid having an inversely tapered shape. Each recess 23 has an inner wall of a polygonal shape composed of flat surfaces. A broken line in the outer periphery of the light-emitting device indicates that the outer periphery of the light-emitting device has an inversely tapered shape. The other structures of the first embodiment are the same as those of the first comparative example. The inversely tapered shape is defined so that the area at the cross section of the recesses 23 in the direction horizontal to the substrate 10 gradually decreases from the first semiconductor layer 15 to the second semiconductor layer 19. FIG. 9 schematically shows a SEM cross-section of the recess 23 having the inversely tapered shape in a section of B-B shown in FIG. 8A. As shown in FIG. 9, the recess 23 and the substrate 10 form an angle of 42.9°. The inventors have confirmed that the angle formed by the recess 23 and the substrate 10 ranges from 40° to 45°. It is conceivable from the above angle and direction [100] in which the side surface of the recess 23 crosses the substrate 10 that the side surface of the recess 23 has a (10-1-2) plane or (30-3-8) plane. Now, it should be noted that a (11-20) plane may be wet etched by thermal phosphoric acid. With the above in mind, it is conceivable that the side surface of the recess 23 formed by the hole having the inversely tapered shape may be a (30-3-8) plane having a similar atomic arrangement to that of the (11-20) plane.

A description will be given, with reference to FIGS. 10A through 12C, of a method for fabricating the light-emitting device in accordance with the first embodiment.

Referring to FIG. 10A, provided are the third semiconductor layer 30 of the AlN layer, the Si-doped GaN layer 32, the undoped GaN layer 34, the first semiconductor layer 15 formed by the n-type GaN layer, the active layer 17 formed by the multiplayer of InGaN/GaN, and the second semiconductor layer 19 formed by the p-type GaN layer having a conduction type opposite to that of the n type in that order. Referring to FIG. 10B, the wafer is annealed in a nitrogen atmosphere at 750° C. for 10 minutes, so that the second semiconductor layer 19 can be activated. Then, patterning is performed using photoresist. Thereafter, the first semiconductor layer 15, the active layer 17 and the second semiconductor layer 19 are etched up to a depth of 0.1 μm from the active layer 17 by using an ICP-RIE (Induced Coupled Plasma Reactive Ion Etcher) apparatus with a gas mainly containing Cl₂. Referring to FIG. 10C, the ITO layer 35 having a thickness of 200 angstroms is formed by electron beam evaporation with a source of a composite oxide of In₂O₃ by 90 wt % and SnO₂ by 10 wt %. The In composite ratio of the ITO layer 35 is 10%. The wafer is then annealed in an air atmosphere at 500° C., so that the ITO layer 35 becomes optically transparent. Then, the ITO layer 36 having a thickness of 2500 angstroms is formed using an RF magnetron sputtering apparatus with a target of a composite oxide of In₂O₃ by 90 wt % and SnO₂ by 10 wt % and using Ar gas plasma to which oxygen having an oxygen partial pressure of 1.9×10⁻³ Pa is added at a plasma power of 100 W, a pressure of 0.4 Pa and a temperature of 200° C.

Referring to FIG. 11A, patterning is performed using photoresist, and the ITO layer 35 and the ITO layer 36 are etched with aqua regalis of HNO₃:HCl:H₂O=0.08:1:1 at 45° C. Referring to FIG. 11B, the SiO₂ layer 40 having a thickness of 1.0 μm is formed by the RF magnetron sputtering apparatus, and patterning is then performed with photoresist. Then the SiO₂ layer 40 is etched by the TCP-RIE apparatus with CF4 gas. Referring to FIG. 11C, dry-etched are the second semiconductor layer 19, the active layer 17, the first semiconductor layer 15, the undoped GaN layer 34, the Si-doped GaN layer 32 and the third semiconductor layer 30 by the ICP-RIE apparatus with the SiO₂ layer 40 being as mask using a gas mainly containing Cl₂. The above dry etching results in the recesses 23 formed by the circular holes penetrated from the second semiconductor layer 19 to the third semiconductor layer 30. That is, the recesses 23 that are penetrated from the second semiconductor layer 19 to the first semiconductor layer 15 can be formed.

Referring to FIG. 12A, the recesses 23 are put in thermal phosphoric acid at 100° C. used as an etchant (etching solution) for 100 minutes, so that the recesses 23 are wet etched so as to have an inversely tapered shape. The factor of causing the recesses 23 to be formed into the inversely tapered shape is an arrangement in which the surface of the GaN film closer to the substrate is an N (nitride) polar surface and the surface thereof farther from the substrate is Ga (gallium) polar surface. In wet etching by thermal phosphoric acid, the AlN layer is etched easily and etching of the GaN film goes on from only the N polar surface. When the recesses 23 are wet etched by thermal phosphoric acid, the third semiconductor layer 30 of the AlN layer is etched first, and the N polar surface of the GaN film close to the substrate 10 is then etched. The wet etching using thermal phosphoric acid forms the recesses 23 into the inversely tapered shape in which the recesses 23 gradually narrow from the first semiconductor layer 15 towards the second semiconductor layer 19.

Referring to FIG. 12B, patterning is performed with photoresist, and the SiO₂ layer 40 is etched with buffered hydrofluoric acid. Thereafter, an n-type contact electrode 42 is formed in the etched portion of the SiO2 layer 40 by evaporation and liftoff. The n-type contact electrode 42 is composed of Ta (tantalum)/Al (aluminum)/Pt (platinum) from the side of the substrate 10. Referring to FIG. 12C, the n-type contact electrode 42 is annealed in an air atmosphere at 500° C., and patterning is performed with photoresist. Then, the SiO₂ layer 40 is etched by buffered hydrofluoric acid. Then, Ni (nickel)/Au (gold) is formed in the etched portion of the SiO₂ layer 40 and the n-type contact electrode 42 by evaporation and liftoff, so that the n-type electrode pad 26 and the p-type electrode pad 28 can be formed.

A description will now be given, with reference to FIG. 13A through 15, of a second method for fabricating the light-emitting device in accordance with the first embodiment.

The process up to etching the first semiconductor layer 15, the active layer 17 and the second semiconductor layer 19 is the same as that of the first embodiment shown in FIGS. 10A and 10B. Thus, a description of the identical process will be omitted here. Referring to FIG. 13A, the TTO layer 35 having a thickness of 100 angstroms is formed by electron beam evaporation with a source of a composite oxide of In₂O₃ by 90 wt % and SnO₂ by 10 wt %. The wafer is then annealed in an air atmosphere at 500° C., so that the ITO layer 35 becomes optically transparent. The SiO2 layer 40 having a thickness of 1.0 μm is formed by the RF magnetron sputtering apparatus. Then, patterning is performed with photoresist, and the SiO₂ layer 40 is etched by the ICP-RIE apparatus with CF4 gas.

Referring to FIG. 13B, dry etched are the ITO layer 35, the second semiconductor layer 19, the active layer 17, the first semiconductor layer 15, the undoped GaN layer 34, the Si-doped GaN layer 32 and the third semiconductor layer 30 by the ICP-RIE apparatus with the SiO₂ layer 40 being used as mask with a gas mainly containing Cl₂. This dry etching results in the recesses 23 formed by the circular holes penetrated up to the third semiconductor layer 30. That is, the recesses 23 that are penetrated from the second semiconductor layer 19 to the first semiconductor layer 15 are formed.

Referring to FIG. 13C, the recesses 23 are put in thermal phosphoric acid at 100° C. used as an etchant for 100 minutes, so that the recesses 23 are wet etched so as to have an inversely tapered shape. At that time, the side surface of the ITO layer 35 contacts thermal phosphoric acid. Now, it should be noted that the ITO layer 35 is grown by electron beam evaporation and contains a very small amount of oxygen. Thus, the ITO layer 35 is not etched by thermal phosphoric acid well.

Referring to FIG. 14A, the SiO₂ layer 40 is removed. Then, the ITO layer 36 having a thickness of 2500 angstroms is formed using an RF magnetron sputtering apparatus with a target of a composite oxide of In₂O₃ by 90 wt % and SnO₂ by 10 wt % and using Ar gas plasma to which oxygen having an oxygen partial pressure of 1.9×10⁻³ Pa is added at a plasma power of 100 W, a pressure of 0.4 Pa and a temperature of 200° C.

Referring to FIG. 14C, patterning is performed with photoresist, and the ITO layer 35 and the ITO layer 36 are etched with aqua regalis of HNO₃:HCl:H₂O=0.08:1:1 at 45° C. Referring to FIG. 14C, patterning is performed with photoresist, and the n-type contact electrode 42 of Ta/Al/Pt is formed by evaporation and liftoff. Referring to FIG. 15, the n-type contact electrode 42 is annealed in an air atmosphere at 500° C. Then, the n-type electrode pad 26 of Ni/Au and the p-type electrode pad 28 are formed. Through the above-mentioned process, the light-emitting device of the first embodiment is completed.

FIG. 16 is a graph of the light output vs. current characteristics of the light-emitting device of the first embodiment and that of the first comparative example. The horizontal axis denotes current (mA) and the vertical axis denotes light output (mW). It can be seen from FIG. 16 that the light output of the first embodiment is greater than that of the first comparative example. For example, for a current of 10 mA, the first embodiment produces power as much as 0.9 mW, and the first comparative example produces power of 0.5 mW. That is, the first embodiment produces light power approximately equal to 1.9 times the light power of the first comparative example. The light output of the first comparative example is approximately 2.6 times that of the first related art that does not have any recess 23.

FIG. 17 shows improvements in light extraction in accordance with the first embodiment. Referring to FIG. 17, the recesses 23 are formed into the inversely tapered shape. Light (a) that is almost half of light incident to the side surface of the recess 23 at angles greater than or equal to the critical angle is changed to light propagated towards the light extraction surface 20 due to the reflection by the side surface at the recess 23. The remaining light (b) that is almost the other half is repeatedly reflected by the side surfaces of the recesses 23 and the substrate 10, and is mostly changed to light propagated towards the light extraction surface 20. Thus, light incident to the side surfaces of the recesses 23 at angles greater than or equal to the critical angle are mostly changed to light propagated towards the light extraction surface 20, and are emitted outside through the light extraction surface 20.

Light that is incident to the side surfaces of the recesses 23 at angles smaller than the critical angle enters into the recesses 23. The recesses are full of air. Thus, light that has been propagated through the first semiconductor layer 15, the active layer 17 and the second semiconductor layer 19 travels from GaN (a relative index of 2.4) having a high refraction index to air having a low refraction index. Thus, light oriented downwards with respect to the normal line of the side surface of the recess 23, that is, light (c) located below the normal line of the side surface of the recess 23 is turned to the direction perpendicular to the substrate 10 due to the Snell's law when entering into the recess 23, and is propagated through the substrate 10. Light that enters into the substrate 10 and is incident to the lower surface of the substrate 10 at angles smaller than the critical angle is emitted outside through the lower surface of the substrate 10. In contrast, light that is incident to the lower surface of the substrate 10 at angles greater than or equal to the critical angle is reflected by the lower surface and is horizontally propagated through the substrate 10. Then, the light is emitted outside through the side surface of the substrate 10. In contrast, light that is oriented closer to the horizontal direction than the normal line of the side surface of the recess 23, that is, light located above the normal line of the side surface of the recess 23 is partially emitted directly outside of the upper portion of the recess 23 as light (d) due to the snell's law when entering into the recess 23, and the remaining light (e) travels to the opposite surface of the recess 23 and passes through this surface. At that time, the light (e) is turned towards the light extraction surface 20 due to the Snell's law when passing through the above-mentioned opposite surface of the recess 23. Then, the light (e) is emitted outside of the light extraction surface 20 directly or through multiple reflections.

Since the substrate 10 does not have the active layer 14, loss resulting from light absorption does not occur. Thus, the light emitted outside of the side surface of the substrate 10 after propagation through the substrate 10 can be more efficiently extracted than light emitted outside of the side surface after propagation through the GaN semiconductor layer 13.

According to the first embodiment, since the recesses 23 are formed into the inversely tapered shape, at least half of light propagated in the direction horizontal to the substrate 10 and at least half of light propagated in the direction perpendicular to the substrate 10 can be extracted outside of the light extraction surface 20. Thus, the first embodiment has greater efficiency of light extraction than the second related art with the holes 22 or the fourth related art with the light extraction surface having a relief structure.

According to the first embodiment, light that goes toward the substrate 10 after entering into the recesses 23 is horizontally propagated through the substrate 10 and is emitted through the side surface of the substrate 10 except light emitted through the lower surface of the substrate 10. Light emitted through the side surface of the substrate 10 can be detected as a light output. It is thus possible to further improve the efficiency of light extraction, as compared to the third related art in which light entering into the reflection grooves 24 is emitted outside thereof.

According to the first embodiment, the recesses 23 are formed into the inversely tapered shape. It is thus possible to secure a sufficient length L2 of the active layer 14 in the direction horizontal to the substrate 10 as shown in FIG. 17, as compared to the third related art in which the reflection grooves 24 are formed into a wedge shape. The first embodiment is capable of emitting a larger amount of light than the third related art.

According to the first embodiment, the recesses 23 formed into the inversely tapered shape are penetrated through up to the third semiconductor layer 30 and reaches the substrate 10. It is thus possible to secure a large area S1 of the side surface of the recesses 23 (see FIG. 17), as compared to the third related art in which the wedge-shaped reflection grooves 24 do not reach the substrate 10. It is therefore possible to reflect a larger amount of light propagated through the first semiconductor layer 15, the active layer 17 and the second semiconductor layer 19 towards the light extraction surface 20. This results in an increased amount of light emitted outside of the light extraction surface 20, so that the efficiency of light extraction can be improved as compared to the third related art.

According to the first embodiment, the recesses 23 formed into the inversely tapered shape are realized in the third semiconductor layer 30, the first semiconductor layer 15, the active layer 17 and the second semiconductor layer 19. It is thus possible to manufacture the light-emitting device easily, as compared to the fourth related art that needs formation of convex portions on the substrate 10 made of sapphire that is very rigid.

In the foregoing description, the recesses 23 shaped into inverse taper are penetrated through up to the third semiconductor layer 30 and reach the substrate 10. However, the present invention is not limited to the above structure but may be varied so that the recesses 23 are penetrated through up to at least the first semiconductor layer 15. Even in this variation, light generated in the active layer 17 can be reflected towards the light extraction surface 20. Preferably, the recesses 23 pass through up to the third semiconductor layer 30 and reach the substrate 10 because an increased area S1 of the side surface of each recess 23 is capable of reflecting an increased amount of light towards the light extraction surface 20.

The above-mentioned first embodiment has an exemplary layer structure such that the first semiconductor layer 15 is an n-type GaN layer, the active layer 17 is a multiplayer of InGaN/GaN, and the second semiconductor layer 19 is a p-type GaN. The present invention is not limited to the above layer structure but may be configured so that the first semiconductor layer 15 is a p-type GaN layer, and the second semiconductor layer 19 is an n-type GaN. The first semiconductor layer 15, the active layer 17 and the second semiconductor layer 19 may be made of other GaN-based semiconductors or semiconductors other than the GaN-based semiconductors.

In the foregoing, the third semiconductor layer 30 formed between the substrate 10 and the active layer 17 is an AlN layer. The third semiconductor layer 30 may be made of a material containing Al and N, such as AlGaN. The use of Al and N makes it easy to form the recesses 23 into the inversely tapered shape.

In the foregoing, the third semiconductor layer 30 contacts the substrate 10. However, the third semiconductor layer 30 it not limited to the above but may be arranged between the substrate 10 and the active layer 17. The inversely tapered recesses 23 penetrated through up to the first semiconductor layer 15 can be formed easily.

The substrate 10 is not limited to the sapphire substrate but may be another substrate such as a SiC substrate, a Si substrate or a GaN substrate.

The etching solution is not limited to thermal phosphoric acid at 100° C. but may be any material capable of forming the recesses 23 into the inversely tapered shape, such as a sodium hydroxide solution, a potassium hydroxide solution, or a mixed acid containing phosphoric acid.

The recesses 23 are not limited to the circular shape in the cross-section horizontal to the substrate 10 but may have another cross-sectional shape such as an oval, square or rectangular cross section.

FIG. 18A shows a relationship between the angle of the side surface of the light-emitting device and the efficiency of light extraction, and FIG. 18B is a cross-sectional view of a light-emitting device (second comparative example) used in an experiment for the measurement of FIG. 18A. The light-emitting device of the second comparative example has the GaN semiconductor layer 13 on the substrate 10. The angle formed by the side surface of the GaN semiconductor layer 13 and the normal line of the substrate 10 is defined as a side surface angle 21 of the light-emitting device. The side surface angle 21 is positive when the GaN semiconductor layer 13 has an inversely tapered shape. Referring to FIG. 18A, the efficiently of light extraction is abruptly improved when the side surface angle 21 is equal to or greater than 20°. The relationship between the side surface angle 21 of the light-emitting device of the second comparative example and the efficiency of light extraction may be applied to the light-emitting device of the first embodiment. Thus, it is preferable that the angle formed by the side surface of each recess 23 and the normal line of the substrate 10 is equal to or greater than 20°. More preferably, the angle formed by the side surface of each recess 23 and the normal line of the substrate 10 is equal to or greater than 30°. Much more preferably, the angle formed by the side surface of each recess 23 and the normal line of the substrate 10 is equal to or greater than 40°.

### Second Embodiment

FIG. 19A is a plan view of a light-emitting device in accordance with a second embodiment, and FIG. 19B is a cross-sectional view taken along a line A-A shown in FIG. 19A. Referring to FIGS. 19A and 19B, the recesses 23 having the inversely tapered shape are provided between the n-type electrode pad 26 and the p-type electrode pad 28. The recesses 23 are grooves that run in any of directions [100], [010], and [110] of GaN. There are also directions [-100], [0-10] and [-1-10] that are 180 different from [100], [010], and [110], respectively. However, there are substantially three directions of [100], [010], and [110]. In FIG. 19A, assuming that the direction at the grooves that extend laterally on the left side of the figure is [100], grooves are formed in directions [010] and [110]. The other structures of the second embodiment are the same as those of the first embodiment shown in FIGS. 8A and 8B.

According to the second embodiment, the recesses 23 that are grooves run in any of directions [100], [010], and [110] of GaN. It is thus possible to prevent the width of the recesses 23 formed by the grooves from increasing in wet etching for defining the inversely tapered shape. It is thus possible to prevent the area of the active layer 17 from being reduced and prevent reduction in the amount of emission of light.

### Third Embodiment

FIG. 20 is a cross-sectional view of a light-emitting device in accordance with a third embodiment. Referring to FIG. 20, a relief structure is formed on the light extraction surface 20 of the surface of the second semiconductor layer 19. The other structures of the third embodiment are the same as those of the first embodiment shown in FIGS. 80 and 17.

The relief structure formed on the surface of the second semiconductor layer 19 results in multiple directions of critical angle. Thus, light that is incident to the flat surface of the second semiconductor layer 19 at angles greater than the critical angle may pass through by the relief structure of the third embodiment shown in FIG. 20 because the light can be incident thereto at angles equal to or less than the critical angle in FIG. 20. Thus, the third embodiment has improved efficiency of light extraction.

### Fourth Embodiment

FIG. 21 is a cross-sectional view of a light-emitting device in accordance with a fourth embodiment. On the third semiconductor layer 30, provided are the first semiconductor layer 15, the active layer 17 and the second semiconductor layer 19 in that order. Holes 44 are penetrated through the second semiconductor layer 19, the active layer 17, the first semiconductor layer 15 and the third semiconductor layer 30. The holes 44 are formed into an inversely tapered shape such that the holes 44 gradually become narrow towards the second semiconductor layer 19 from the third semiconductor layer 30.

According to the fourth embodiment, the length L3 of the active layer 17 can be lengthened, as compared to the third related art. Thus, the fourth embodiment has a larger amount of emission of light than the third related art. Further, the area S2 of the side surface of each hole 44 is greater than that of the third related art. It is thus possible to reflect an increased amount of light propagated through the semiconductor layer 15, the active layer 17 and the second semiconductor layer 19 towards the light extraction surface 20, as compared to the third related art. Thus, an increased amount of light is emitted outside of the light extraction surface 20, and the efficiency of light extraction can be improved.

The fourth embodiment does not employ the substrate 10, and may be mounted directly on a board having excellent heat radiation. Thus, the fourth embodiment has better heat radiation than the first embodiment with the sapphire substrate 10.

The fourth embodiment may be varied so that the surface of the second semiconductor layer 19 has a relief structure as in the case of the third embodiment, so that similar advantages to those of the third embodiment can be obtained.

The present invention is not limited to the specifically described embodiments, but other embodiments and variations may be made within the scope of the present invention.

The present application is based on Japanese Patent Application No. 2006-324579 filed on Nov. 30, 2006, the entire disclosure of which is hereby incorporated by reference.

What is claimed is:

1. A method for fabricating a light-emitting device comprising:
forming a first semiconductor layer on a substrate;
forming an active layer on the first semiconductor layer;
forming a second semiconductor layer on the active layer, the second semiconductor layer having a conduction type opposite to that of the first semiconductor layer; and
forming a recess so as to be penetrated through up to the first semiconductor layer from the second semiconductor layer by a first etching; and
forming an inversely tapered shape to an inner wall of the recess by a second etching using an etching solution.

2. The method as claimed in claim 1, wherein the etching solution of the second etching uses one of a sodium hydroxide solution, a potassium hydroxide solution, a phosphoric acid and a mixed acid containing phosphoric acid.

3. The method as claimed in claim 1, wherein a third semiconductor layer containing Al and N is interposed between the substrate and the first semiconductor layer, and the first etching forms the recess that reaches the third semiconductor layer.

4. The method as claimed in claim 3, wherein the first semiconductor layer comprises GaN, and the third semiconductor layer comprises one of AlN and AlGaN.

5. The method as claimed in claim 1, wherein the recess comprises a hole.

6. The method as claimed in claim 5, wherein an inner wall of the recess has a polygonal shape composed of multiple flat surfaces.

7. The method as claimed in claim 1, wherein the recess comprises a groove.

8. The method as claimed in claim 1, wherein the recess comprises grooves that extend in different directions.

9. The method as claimed in claim 1, wherein the first semiconductor layer, the active layer and the second semiconductor layer are respectively GaN-based semiconductor layers.

10. The method as claimed in claim 1, wherein an angle between a side surface of the recess and a normal line of the substrate is equal to or greater than 20°.

11. The method as claimed in claim 1, wherein the second semiconductor layer has a surface having a relief structure.

12. The method as claimed in claim 1, wherein the substrate is one of sapphire, SiC, Si and GaN.
